(19) United States
(12) Patent Application Publication
(10) Pub. No.: US 2019/0056432 A1
(43) Pub. Date: Feb. 21, 2019

(54) RFID BASED ENERGY MONITORING DEVICE

(71) Applicant: AVERY DENNISON RETAIL INFORMATION SERVICES, LLC, Mentor, OH (US)

(72) Inventor: Ian J. FORSTER, Chelmsford (GB)

(21) Appl. No.: 16/106,737

(22) Filed: Aug. 21, 2018

Related U.S. Application Data
(60) Provisional application No. 62/548,105, filed on Aug. 21, 2017.

(51) Int. Cl. G01R 15/18; G01R 19/00

(52) U.S. Cl. CPC G01R 15/18; G01R 19/0092

(57) ABSTRACT

A device configured to fit between an electric plug and an electric wall outlet for monitoring the energy consumption of an electrically powered device such as an appliance. The monitoring device enables energy consumption to be measured over time and reported to an RFID reader without the need to interrupt the power supply to the device being monitored. The monitoring device comprises a detection circuit coupled to a transmission system attached to a thin, planar base. A field powering element within the detection circuit is used to achieve electric field powering of the monitoring device.

### CROSS-REFERENCE TO RELATED APPLICATION(S)

The present application claims priority and the benefit of U.S. provisional patent application No. 62/548,105 filed on Aug. 21, 2017, which is incorporated herein by reference in its entirety.

### BACKGROUND

The present invention relates generally to a radio frequency identification device (RFID) for monitoring the energy consumption of electronically powered devices such as fixtures, accessories, appliances, etc. The RFID monitoring device is designed to fit between a typical electrical cord plug and an electrical wall outlet, and is a relatively low cost, easily deployed energy consumption monitoring device, to assist users with energy conservation measures in homes, workplaces, and other settings where electrical power is consumed.

Energy efficiency is an important consideration when deciding to purchase an electrically powered device such as an appliance. Many appliances sold today, such as refrigerators, televisions, electric ovens, air conditioners, dehumidifiers, electric hot water tanks, electric dryers and washing machines, are required to have an energy guide label that provides the user with an estimated annual energy usage and associated cost to operate the appliance. However, energy guide labels are only estimates and there are still many appliances and electronic devices that are not required to provide this type of information and/or that lose energy efficiency over time. A user can also attempt to determine energy costs by multiplying the advertised energy usage of the device or appliance times the estimated time usage of the device, but this is an inexact approach at best and provides limited useful information. It may also not accurately predict energy consumption of a device that loses efficiency over time, which may prevent a user from determining when it's appropriate to replace a device or appliance that is no longer energy efficient.

A plug-in type energy usage monitor can be used to provide a more accurate depiction of energy usage and the cost to operate an electrically powered device such as an appliance, but suffers from a number of limitations. For example, these types of monitors typically plug into an outlet and the appliance plugs into the monitor, and requires the user to periodically go back and read the monitor display information at a desired time interval. However, these types of monitors are bulky and interrupt the flow of current to the device or appliance, which can result in damage thereto. Additionally, these types of monitors are typically not designed for use on 220 volt appliances such as dryers and air conditioners so their usefulness is limited. They also cannot be read remotely. A whole house monitoring system may be employed to measure these appliances, but there is no way to accurately isolate energy usage to a single appliance using a whole house system so use of such systems is also limited, not to mention expensive.

Thus, there exists a long felt need in the art for a thin, relatively low cost, planar device designed to monitor the energy consumption of individual electronic devices and appliances in the home, workplace or other settings. Determining energy consumption of a particular device or appliance and its associated cost to operate are important considerations when purchasing an appliance or deciding when to replace one that has lost efficiency over time. The present invention discloses a low-profile monitoring device that is designed to fit between an electric cord plug and an electric wall outlet, wherein the plug's pins are permitted to pass through the monitoring device. There also exists a long felt need for a monitoring device that may be powered with the voltage on the plug pins and that monitors energy consumption over time without interrupting the flow of current to the device or appliance. Finally, there is a long felt need for an energy consumption monitoring device that can be interrogated using RFID technology to allow a user to monitor energy consumption from a remote location, and for use in measuring the energy consumption of low, medium, and high load electrical devices and appliances.

### SUMMARY

The following presents a simplified summary in order to provide a basic understanding of some aspects of the disclosed innovation. This summary is not an extensive overview, and it is not intended to identify key/critical elements or to delineate the scope thereof. Its sole purpose is to present some concepts in a simplified form as a prelude to the more detailed description that is presented later.

The subject matter disclosed and claimed herein, in one aspect thereof, comprises an electrical current monitoring device for monitoring energy usage of an electrically powered device or appliance. The monitoring device comprises a relatively thin, planar base adapted to receive a plug from the appliance, a transmission system, and a detection circuit for measuring electrical current usage of the appliance. The detection circuit comprises a pair of current sensing coils surrounding a pair of apertures in the base configured to receive a pair of pins from the plug. Each of the current sensing coils is electrically connected to the transmission system via a first pathway and a second pathway. The first pathway forms a connection between the sensing coils and a RFID chip. The second pathway comprises a field powering element for achieving electric field powering. More specifically, the monitoring device may be powered by either an electric field present on the pair of pins from the plug and/or a voltage induced in the pair of current sensing coils when the electrically powered device is drawing current.

According to another aspect of the present invention, the transmission system comprises a RFID device that further comprises a RFID chip and at least one antenna in communication with the RFID chip for transmitting a RFID signal from the monitoring device to a RFID reader. The RFID reader may be positioned remotely from the monitoring device and may be used to monitor the electrical consumption of multiple electronic devices, such as appliances, positioned within a given interrogation space.

In accordance with an alternative embodiment of the present invention, the monitoring device comprises a base adapted to receive a plug from the appliance, a transmission system, and a detection circuit for measuring current usage. The detection circuit comprises a pair of current sensing coils surrounding a pair of apertures in the base configured to accept a pair of pins from an electrical cord plug. Each of the current sensing coils is electrically connected to the transmission system via a first pathway and a second pathway. The detection circuit further comprises a capacitor component located along the second pathway for achieving electric field powering.

In accordance with yet another embodiment of the present invention, the monitoring device comprises a base adapted to receive an electrical cord plug from the appliance, a transmission system, and a detection circuit for measuring current usage by the appliance. The detection circuit comprises a pair of current sensing coils surrounding a pair of apertures in the base configured to accept a pair of pins from the electrical cord plug. Each of the current sensing coils is electrically connected to the transmission system via a first pathway and a second pathway. The detection circuit further comprises a resistor component located along the second pathway for achieving electric field powering.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and is intended to include all such aspects and their equivalents. Other advantages and novel features will become apparent from the following detailed description when considered in conjunction with the drawings.

### BRIEF DESCRIPTION OF THE DRAWINGS

FIG. 1 illustrates a perspective view of one embodiment of an energy monitoring device of the present invention in accordance with the disclosed architecture.

FIG. 2 illustrates a schematic view of the energy monitoring device of FIG. 1 positioned between an electrical cord plug and an electric wall outlet in accordance with the disclosed architecture.

FIG. 3 illustrates a perspective view of an alternative embodiment of the energy monitoring device of the present invention comprising a capacitor component in accordance with the disclosed architecture.

FIG. 4 illustrates a perspective view of yet another alternative embodiment of the energy monitoring device of the present invention comprising a resistor component in accordance with the disclosed architecture.

### DETAILED DESCRIPTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof.

The present invention discloses a relatively thin, low cost, planar electrical monitoring device configured to monitor the energy consumption of electrically powered devices, such as appliances. The monitoring device is designed to fit between an electric cord plug and an electric wall outlet without interrupting the flow of current to the electrically powered device or appliance. More specifically, the plug pins or prongs pass through apertures in the base of the monitoring device. By drawing electrical power from the voltage flowing through the plug pins, via capacitance or a high resistance connection, the monitoring device is able to monitor energy consumption of the electrically powered device or appliance over time and report such energy consumption information to a user via RFID technology.

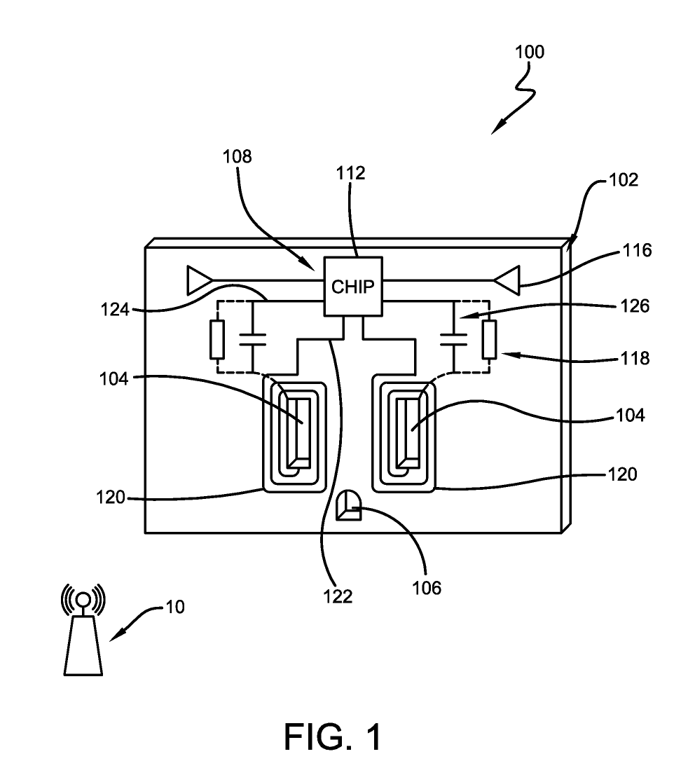

Referring initially to the drawings, FIG. 1 illustrates a perspective view of an energy or current monitoring device 100 of the present invention. The monitoring device 100 comprises a base 102, a transmission system 108, and a detection circuit 118. Base 102 is substantially configured as a thin, planar card and comprises a pair of spaced apart continuous openings or apertures 104 arranged to receive a pair of pins 22 from an electrical cord plug 20 attached to a device or appliance 50 that uses alternating or direct electrical current as its power source. The base 102 may further comprise a ground prong aperture 106 to accommodate a ground prong (not shown) from the plug 20. The pair of apertures 104 and ground prong aperture 106 may be configured to accept any pins, prongs, blades, or the like used on appliance plugs 20 anywhere throughout the world.

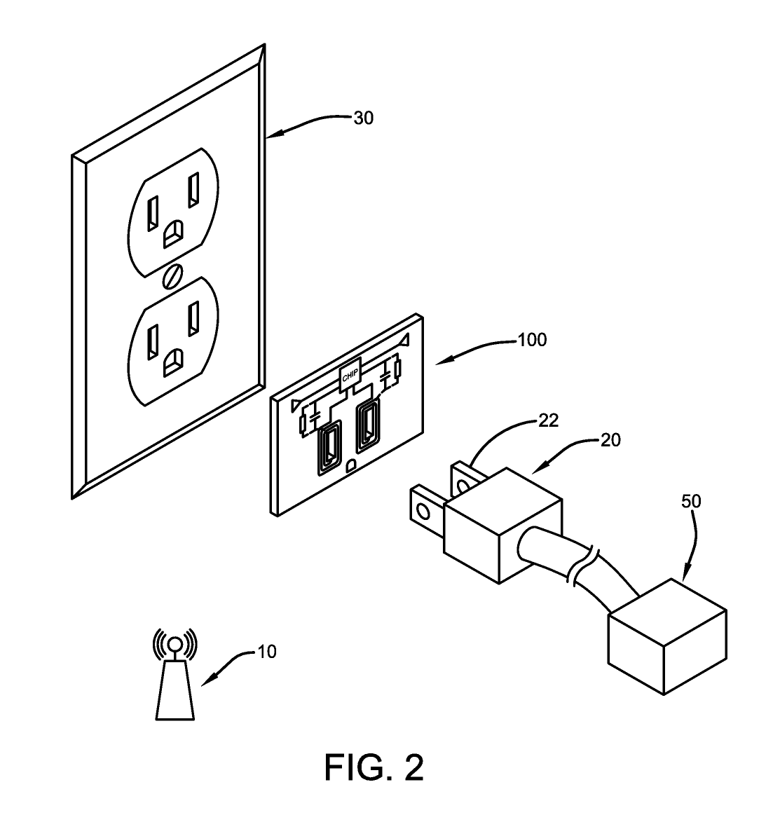

As best shown in FIG. 2, the current monitoring device 100 is positioned between plug 20 and electric wall outlet 30. More specifically, pins 22 of plug 20 pass through apertures 104 and into wall outlet 30. Accordingly, while base 102 can be manufactured in a variety of different shapes and sizes to suit user preference, it is preferably thin enough to allow the pair of pins 22 from the plug 20 to penetrate the pair of apertures 104 into the wall outlet 30 without interrupting the flow of electrical current to device or appliance 50.

The base 102 may be colored, dyed or have other indicia to indicate a particular load detection range for monitoring device 100. For example, different colored bases 102 could be used to indicate use with low, medium, and high load devices or appliances 50, thereby enabling individual monitoring devices 100 to be designed so that the measurement dynamic range is reduced for individual designs for different applications.

Transmission system 108 is attached to, mounted on, embedded within, or otherwise affixed to base 102, and the detection circuit 118 is coupled to the transmission system 108 so that an electrical current may flow throughout. The detection circuit 118 is similarly attached to or alternatively printed onto base 102, as desired. As best illustrated in FIGS. 1, 3 and 4, transmission system 108 further comprises a RFID device 110. RFID device 110 and detection circuit 118 may be manufactured using any method commonly associated with the fabrication of RFID tags. RFID device 110 may comprise a RFID chip 112 and at least one antenna 116 in communication with RFID chip 112. The at least one antenna 116 may be any of a wide variety of types of antennas such as, but not limited to, loop antennas, slot antennas, sloop antennas, dipole antennas, and hybrids and combinations of these types of antennas, many of which are manufactured and sold by Avery Dennison Corporation of Pasadena, Calif. The RFID chip 112 itself may comprise an internal memory (not shown), and is powered as described supra.

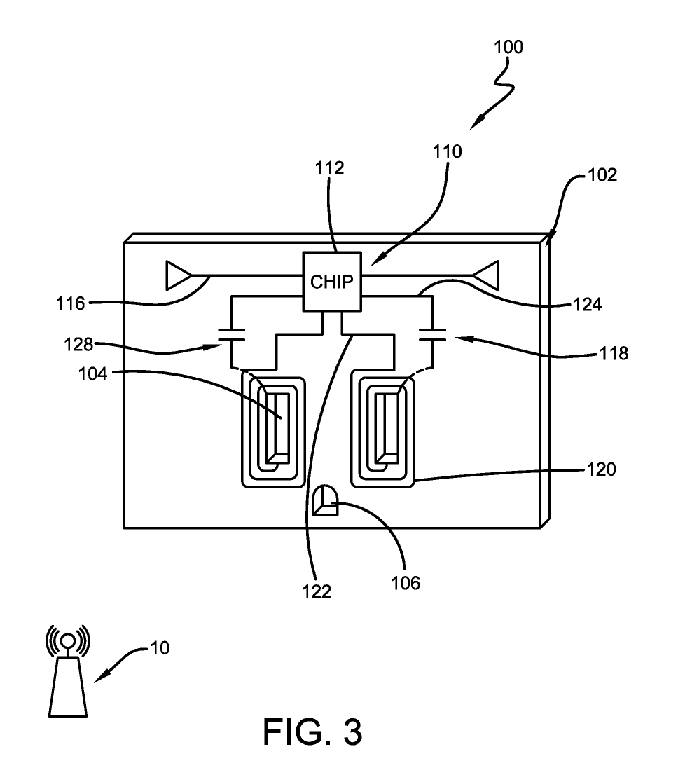

Detection circuit 118 comprises a pair of current sensing coils 120 and a field powering element 126. Each of the pair of current sensing coils 120 wraps, encircles, or otherwise surrounds, or is positioned adjacent to, one of the pair of apertures 104 in the base 102. Each of the pair of current sensing coils 120 is coupled to transmission system 108 via a first pathway 122 and a second pathway 124. Typically, each first pathway 122 connects the corresponding current sensing coil 120 directly to RFID chip 112. Each second pathway 124 connects the corresponding current sensing coil 120 to RFID chip 112 impeded by a field powering element 126. In a preferred embodiment of the present invention, field powering element 126 may comprise a pair of capacitor components 128 coupled to transmission system 108. As best shown in FIG. 3, each capacitor component 128 is positioned inline along the second pathway 128 between the corresponding current sensing coil 120 and RFID chip 112. In addition to capacitance, the field powering element 126 may achieve an electric field powering via resistance, or induction using components such as, but not limited to, capacitors, resistors, inductors, diodes, and combinations thereof.

RFID chip 112 is powered by either the electric field present on the plug pins 22, a voltage induced in the pair of current sensing coils 120 when device or appliance 50 is drawing current, or both. In other words, each of the pair of current sensing coils 120 convert electric current flowing there-through into voltage. Conversely, when a voltage is applied to the pair of current sensing coils 120, a current is induced. The electric field powering may be achieved by creating a capacitor between circuit elements on the current monitoring device 100 and the plug pins 22 penetrating monitoring device 100. The magnetic field powering and sensor input is achieved by using one or more of the pair of current sensing coils 120 positioned around plug pins 22.

Alternatively, a highly resistivity material or an insulator, such as a coated plastic, may be used to contact plug pins 22. This is permissible as the RFID chip 112 requires very little power to operate. In one example, approximately 1 μA at 1V, with United States voltage, approximately 100V AC, and a 100×10⁶ ohm resistance would provide sufficient power to operate monitoring device 100.

The transmission system 108 is interrogated by either a RFID reader 10, which communicates via the at least one antenna 116, or alternatively via modulated communication signals present on the mains wiring of the electrical grid. The mains frequency provides a time base, allowing the RFID chip 112 to record the integral of current, from the detector circuit 118, and time, as a measure of energy consumption. The RFID chip 112 may further comprise a resettable or permanent counter (not shown) that may record increments for a known value of current over time. In one embodiment, the counter may increment by one for 3000 cycles of the mains at 1 A, or 30,000 cycles at 100 mA, providing a value for the integrated power consumption when combined with the mains voltage.

Communication signals imposed on the wiring itself will generally be at higher frequencies than the AC mains frequency. For example, if the mains frequency is approximately between 50-60 Hz, the communications frequency may be approximately between 1.8 MHz-67.5 MHz for common systems or higher. Higher frequency signals may be connected to the RFID chip 112 via the inductors around the current carrying plug pins, or via capacitor/resistor combinations. Using a tuned circuit at the carrier frequency is particularly effective to filter out unwanted noise.

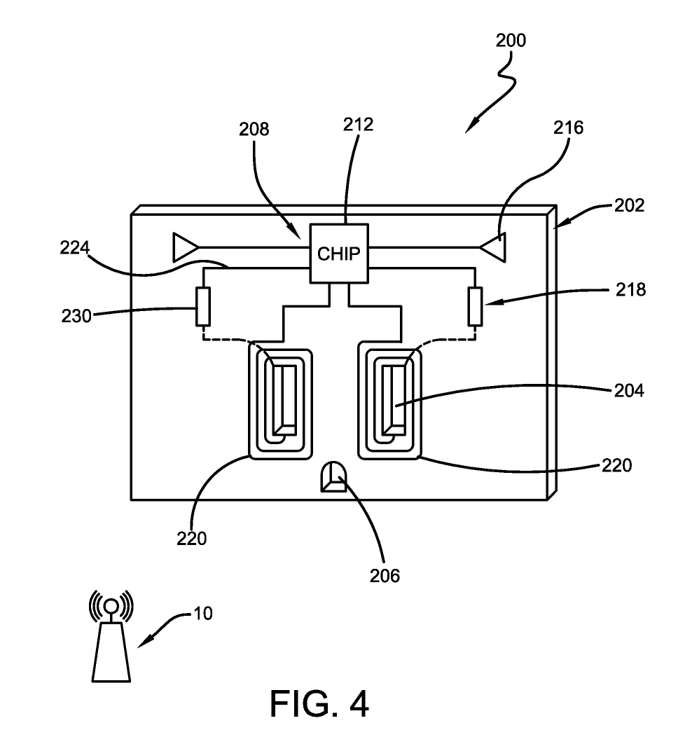

In accordance with another embodiment of the invention, FIG. 4 illustrates a current monitoring device 200 that comprises a base 202 with a pair of apertures 204, a transmission system 208, and a detection circuit 218. The current monitoring device 200 is similar to device 100 and is likewise positioned between the plug 20 and the electric wall outlet 30. The transmission system 208 comprises a RFID chip 212 and at least one antenna 216 coupled to the RFID chip 212. The detection circuit 218 is coupled to the transmission system 208 so that an electric current may flow throughout.

In this particular embodiment, the detection circuit 218 comprises pair of current sensing coils 220 and a resistor component 230. Each of the pair of current sensing coils 220 wraps, encircles, or otherwise surrounds, or is positioned adjacent to, one of the pair of apertures 204 in the base 202. Each of the pair of current sensing coils 220 is coupled to the transmission system 208 via a first pathway 222 and a second pathway 224. Typically, each first pathway 222 connects the corresponding current sensing coil 220 directly to the RFID chip 212. Each second pathway 224 connects the corresponding current sensing coil 220 to the RFID chip 212 impeded by resistor component 230. Each resistor component 230 is positioned inline along the second pathway 128 between the corresponding current sensing coil 120 and the RFID chip 112, as best shown in FIG. 4.

The transmission system 208 is interrogated by either a RFID reader 10, which communicates via the at least one antenna 216, or alternatively via modulated communication signals present on the mains wiring of the electrical grid. The mains frequency provides a time base, allowing the RFID chip 212 to record the integral of current, from the detection circuit 218, and time, as a measure of energy consumption. The RFID chip 212 may further comprise a resettable or permanent counter (not shown) that may record increments for a known value of current over time. In one embodiment, the counter may increment by one for 3000 cycles of the mains at 1 A, or 30,000 cycles at 100 mA, providing a value for the integrated power consumption when combined with the mains voltage.

Communication signals imposed on the wiring itself will generally be at higher frequencies than the AC mains frequency. For example, if the mains frequency is approximately between 50-60 Hz, the communications frequency may be approximately between 1.8 MHz-67.5 MHz for common systems or higher. Higher frequency signals may be connected to the RFID chip 212 via the inductors around the current carrying pins 22, or via capacitor/resistor combinations. Using a tuned circuit at the carrier frequency is particularly effective to filter out unwanted noise.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An electrical current monitoring device comprising:
a base;
a transmission system attached to the base; and
a detection circuit in communication with the transmission system.

2. The electrical current monitoring device of claim 1, wherein the electrical current monitoring device is adapted to be positioned between a plug and a wall outlet.

3. The electrical current monitoring device of claim 1, wherein the transmission system is a RFID device.

4. The electrical current monitoring device of claim 3, wherein the RFID device comprises a RFID chip and at least one antenna.

5. The electrical current monitoring device of claim 1, wherein the transmission system is embedded within the base.

6. The electrical current monitoring device of claim 1, wherein the base comprises a pair of apertures for accepting a pair of pins from a plug.

7. The electrical current monitoring device of claim 1, wherein the detection circuit comprises a field powering element for powering the electrical current monitoring device.

8. The electrical current monitoring device of claim 1, wherein the electrical current monitoring device achieves electric field powering via capacitance.

9. The electrical current monitoring device of claim 1, wherein the electrical current monitoring device achieves electric field powering via resistance.

10. The electrical current monitoring device of claim 1, wherein the detection circuit comprises a pair of current sensing coils.

11. A monitoring device for measuring an amount of electrical current consumed by an electronic device comprising:
a base;
a transmission system attached to the base; and
a detection circuit comprising a capacitor component coupled to the transmission system.

12. The monitoring device of claim 11, wherein the monitoring device is adapted to fit between a plug and a wall outlet.

13. The monitoring device of claim 11, wherein the transmission system comprises a RFID chip and at least one antenna in communication with an RFID reader, and further wherein the RFID reader receives information from the monitoring device about the amount of electrical current consumed by the electronic device.

14. The monitoring device of claim 11, wherein the detection circuit further comprises a pair of sensing coils.

15. The monitoring device of claim 14, wherein each of the pair of sensing coils is in communication with the transmission system via a first pathway and a second pathway.

16. An electrical current monitoring device comprising:
a base;
a transmission system attached to the base; and
a detection circuit comprising a resistor component coupled to the transmission system.

17. The electrical current monitoring device of claim 16, wherein the electrical current monitoring device is positioned between an electrical plug and an electric wall outlet.

18. The electrical current monitoring device of claim 16, wherein the transmission system comprises a RFID chip and at least one antenna.

19. The electrical current monitoring device of claim 16, wherein the detection circuit further comprises a pair of sensing coils.

20. The electrical current monitoring device of claim 19, wherein each of the pair of sensing coils is coupled to the transmission system via a first pathway and a second pathway.
